(19) United States
(12) Patent Application Publication
(10) Pub. No.: US 2017/0032983 A1
(43) Pub. Date: Feb. 2, 2017

(54) SUBSTRATE PROCESSING APPARATUS, SUBSTRATE PROCESSING METHOD, MAINTENANCE METHOD OF SUBSTRATE PROCESSING APPARATUS, AND STORAGE MEDIUM

(71) Applicant: TOKYO ELECTRON LIMITED, Tokyo (JP)

(72) Inventors: Koshi MUTA, Kumamoto (JP); Tsuyoshi MORIYA, Iwate (JP); Takuya MORI, Tokyo (JP); Kazuhiro TAKESHITA, Kumamoto (JP); Tomonori ESAKI, Kumamoto (JP); Kouichi MIZUNAGA, Kumamoto (JP); Masataka TANAKA, Kumamoto (JP); Kouzou KANAGAWA, Kumamoto (JP); Keigo NAKANO, Kumamoto (JP)

(21) Appl. No.: 15/220,653

(22) Filed: Jul. 27, 2016

(30) Foreign Application Priority Data
Jul. 29, 2015 (JP) 2015-149228
May 16, 2016 (JP) 2016-097646

(51) Int. Cl. H01L 21/67; G03F 7/16

(52) U.S. Cl. CPC H01L 21/67017; G03F 7/16; H01L 21/67248

(57) ABSTRACT

A thermal catalytic layer is formed on the inner surface of a processing container and heated. Thus, when a sublimate sublimated from a coating film on a wafer W and received within the processing container reaches the vicinity of the thermal catalytic layer, the sublimate is decomposed and removed by the thermal activation of the thermal catalytic layer. In removing a sublimate attached to a light transmission window, a cleaning substrate formed with the thermal catalytic layer on the surface thereof is carried into the processing container and caused to approach the light transmission window. Thereafter, the cleaning substrate is heated so that the sublimate attached to the surface of the light transmission window is removed.

### CROSS-REFERENCE TO RELATED APPLICATIONS

This application is based on and claims priority from Japanese Patent Application Nos. 2015-149228 and 2016-097646 filed on Jul. 29, 2015 and May 16, 2016, respectively, with the Japan Patent Office, the disclosures of which are incorporated herein in their entirety by reference.

### TECHNICAL FIELD

The present disclosure relates to the field of the technology which processes a substrate by placing the substrate inside a processing container provided with an exhaust passage.

### BACKGROUND

For example, in a manufacturing process of a semiconductor device having a multilayer wiring structure, a processing of forming a coating film (e.g., a resist film or an anti-reflection film) on a semiconductor wafer as a substrate (hereinafter, referred to as a “wafer”) is performed, and subsequently, a heating processing is performed to, for example, dry a solvent remaining in the coating film or facilitate a crosslinking reaction of a crosslinking agent. A heating processing apparatus that has been used for the heating processing has a structure in which a heating plate serving also as a wafer placing table is provided inside a processing container. As a heating unit for heating the wafer, instead of the heating plate, a light emitting diode (LED) light source which is an infrared lamp has also been used.

In this heating processing apparatus, since an organic component within the coating film is sublimated by the heating of the wafer, it is performed to discharge the sublimate through an exhaust passage along with an exhaust flow by purging the inside of the processing container with air or an inert gas. The sublimate is suppressed from being attached to the inner wall of the processing container because the heating temperature increases to a sublimation temperature or higher of the sublimate in order to suppress particle scattering in the processing atmosphere. However, the sublimate introduced into the exhaust passage is easily precipitated at the downstream side of the exhaust passage due to a decrease of the temperature, and hence, a periodic maintenance is required.

In addition, when the LED light source is used as the heating unit, the sublimate is attached to a light transmission window made of, for example, a quartz plate partitioning the atmosphere inside the processing container and the atmosphere where the light source is placed, thereby, deteriorating the luminance. In this case, there has been a necessity to disassemble and clean the apparatus. Further, it is known that in a process of forming a carbon-based film called a spin on cap (SOC) film to become, for example, an etching mask, a processing of planarizing the film is performed by irradiating ultraviolet (UV) rays. However, in this case, the same problem as described above occurs.

In addition, Japanese Laid-Open Patent Publication No. 2014-094464 discloses removal of a polymer by a thermal catalyst. Japanese Laid-Open Patent Publication No. 2014-177523 discloses a processing of decomposing a plastic composite material by a thermal catalyst. However, these related techniques do not disclose removing a sublimate or decomposition residues generated in the substrate processing apparatus.

### SUMMARY

A substrate processing apparatus of the present disclosure includes a processing container provided therein with a placing unit configured to place a processing target substrate thereon, an exhaust passage configured to exhaust the atmosphere inside the processing container, a thermal catalytic material formed in at least one of the inner surface of the processing container and the exhaust passage to be heated and therefore thermally activated to decompose a product generated from the processing target substrate by a processing of the processing target substrate, and a thermal catalyst heating unit configured to heat the thermal catalytic material.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a perspective view illustrating a coating/developing apparatus.

FIG. 2 is a plan view illustrating the coating/developing apparatus.

FIG. 3 is a vertical-sectional side view illustrating a heating processing apparatus according to a first exemplary embodiment.

FIG. 4 is an explanatory view illustrating an operation of the heating processing apparatus.

FIG. 5 is an explanatory view illustrating a maintenance method of a substrate processing apparatus of the present disclosure.

FIG. 6 is an explanatory view illustrating the maintenance method of the substrate processing apparatus of the present disclosure.

FIG. 7 is a vertical-sectional side view illustrating a heating processing apparatus according to a second exemplary embodiment.

FIG. 8 is a plan view illustrating an exhaust passage of the heating processing apparatus.

FIG. 9 is a plan view and a side view illustrating another example of the exhaust passage of the heating processing apparatus.

FIG. 10 is a plan view illustrating another example of the exhaust passage of the heating processing apparatus.

FIG. 11 is a vertical-sectional side view illustrating a planarizing apparatus according to a third exemplary embodiment.

FIG. 12 is an explanatory view illustrating a sublimate generated in the planarizing apparatus.

FIG. 13 is an explanatory view illustrating a maintenance method of the planarizing apparatus.

FIG. 14 is an explanatory view illustrating the maintenance method of the planarizing apparatus.

FIG. 15 is a cross-sectional view illustrating a heating processing apparatus according to a fourth exemplary embodiment.

FIG. 16 is an exploded perspective view illustrating the heating processing apparatus according to the fourth exemplary embodiment.

FIG. 17 is a perspective view illustrating a block body and a thermal catalyst heating unit.

FIG. 18 is a perspective view illustrating a heating processing apparatus and a cross-sectional view of a thermal catalytic unit according to a fifth exemplary embodiment.

FIG. 19 is a cross-sectional view illustrating a heating processing apparatus according to a sixth exemplary embodiment.

FIG. 20 is a plan view illustrating a placing table of the heating processing apparatus according to the sixth exemplary embodiment.

FIG. 21 is an explanatory view illustrating a heating processing apparatus provided with an exhaust pressure measuring unit.

FIG. 22 is a characteristics diagram illustrating a mass change and a heat flow change depending on a temperature in a reference example.

FIG. 23 is a characteristics diagram illustrating a mass change and a heat flow change depending on a temperature change in a comparative example.

### DETAILED DESCRIPTION

In the following detailed description, reference is made to the accompanying drawings, which form a part hereof. The illustrative embodiments described in the detailed description, drawing, and claims are not meant to be limiting. Other embodiments may be utilized, and other changes may be made without departing from the spirit or scope of the subject matter presented here.

The present disclosure has been made under the foregoing circumstances, and an object thereof is to provide a technique in which, in performing a processing on a substrate while exhausting the inside of a processing container, a product generated by the processing of the substrate is decomposed and suppressed from being attached to an exhaust passage. Another object of the present disclosure is to provide a technique in which, in performing a processing on a substrate with light from a light source while exhausting the inside of the processing container, a product generated by the processing of the substrate and attached to a light transmission window is removed.

A substrate processing apparatus of the present disclosure includes a processing container provided therein with a placing unit configured to place a processing target substrate thereon, an exhaust passage configured to exhaust the atmosphere inside the processing container, a thermal catalytic material formed in at least one of the inner surface of the processing container and the exhaust passage to be heated and therefore thermally activated to decompose a product generated from the processing target substrate by the processing of the processing target substrate, and a thermal catalyst heating unit configured to heat the thermal catalytic material.

The above-described substrate processing apparatus further includes a substrate heating unit configured to heat the processing target substrate placed on the placing unit.

In the above-described substrate processing apparatus, the product generated from the processing target substrate is a sublimate.

In the above-described substrate processing apparatus, the exhaust passage includes a pressure loss section where a pressure loss is larger than that in a downstream side thereof, and the thermal catalytic material is provided in the pressure loss section.

The above-described substrate processing apparatus further includes a light source unit configured to irradiate light to the processing target substrate placed on the placing unit, a light transmission window configured to partition the light source unit and the atmosphere inside the processing container, a selection unit configured to select a maintenance mode, and a controller configured to output a control signal to implement a step of carrying a maintenance substrate provided with the thermal catalytic material into the processing container when the maintenance mode is selected, a step of subsequently heating the maintenance substrate by the substrate heating unit in order to thermally activate the thermal catalytic material, and a step of causing the heated maintenance substrate to approach the light transmission window in order to remove the product attached to the light transmission window.

Another substrate processing apparatus of the present disclosure includes a processing container provided therein with a placing unit configured to place a processing target substrate thereon, a substrate heating unit configured to heat the processing target substrate placed on the placing unit, an exhaust passage configured to exhaust the atmosphere inside the processing container, a light source unit configured to irradiate light to the substrate placed on the placing unit, a light transmission window configured to partition the light source unit and the atmosphere inside the processing container, a selection unit configured to select a maintenance mode, and a controller configured to output a control signal to implement a step of carrying, into the processing container when the maintenance mode is selected, a maintenance substrate provided with a thermal catalytic material to be heated and therefore thermally activated to decompose a sublimate as a product generated from the processing target substrate by a processing of the processing target substrate, a step of subsequently heating the maintenance substrate by the substrate heating unit in order to activate the thermal catalytic material, and a step of causing the heated maintenance substrate to approach the light transmission window in order to remove the sublimate attached to the light transmission window.

In the above-described substrate processing apparatus, the light source unit serves also as the substrate heating unit.

In the above-described substrate processing apparatus, the light source unit is an ultraviolet ray irradiating lamp.

In the above-described substrate processing apparatus, the step of causing the heated maintenance substrate to approach the light transmission window is performed by a lift pin configured to hold the substrate from the rear surface thereof and move the substrate up and down.

In the above-described substrate processing apparatus, the thermal catalytic material is formed in a layer shape.

In the above-described substrate processing apparatus, the thermal catalytic material is formed into a block body or a particle body obtained by carrying a thermal catalyst in a porous carrier, and provided to block the exhaust passage.

In the above-described substrate processing apparatus, the thermal catalytic material is configured in the manner that a cartridge accommodated in a case body is mounted to be freely attachable to/detachable from the exhaust passage.

The above-described substrate processing apparatus further includes a measuring unit configured to measure an exhaust pressure or an exhaust flow rate in the exhaust passage, and a controller configured to control the heating temperature of the thermal catalyst heating unit to increase when the exhaust pressure measured in the measuring unit exceeds a set value or the measured exhaust flow rate is less than a set value.

The above-described substrate processing apparatus further includes a controller configured to control the heating temperature of the thermal catalyst heating unit to temporarily increase per cumulative time of a substrate processing or per number of substrates processed.

In the above-described substrate processing apparatus, a plurality of processing containers are provided to have a common exhaust passage provided such that separate exhaust passages provided in the processing containers, respectively, join with each other in the common exhaust passage, and the thermal catalytic material is provided in each of the separate exhaust passages, and a thermal catalytic material formed into a block body or a particle body obtained by carrying a thermal catalyst in a porous carrier is provided to block the common exhaust passage.

A substrate processing method of the present disclosure includes placing a processing target substrate on a placing unit inside a processing container and processing the processing target substrate, exhausting the atmosphere inside the processing container through an exhaust passage, and heating and thermally activating a thermal catalytic material provided in at least one of the inner surface of the processing container and the exhaust passage to decompose a product generated from the processing target substrate by the processing of the processing target substrate.

In the above-described substrate processing method, the processing of the processing target substrate placed on the placing unit is performed in the manner that the substrate is heated by the substrate heating unit.

In the above-described substrate processing method, the thermal catalytic material is formed into a block body or a particle body obtained by carrying a thermal catalyst in a porous carrier and provided to block the exhaust passage, and the method further includes increasing the heating temperature of the thermal catalytic material when an exhaust pressure measured by a measuring unit configured to measure an exhaust pressure or an exhaust flow rate in the exhaust passage exceeds a set value or a measured exhaust flow rate is less than a set value.

The above-described substrate processing method further includes temporarily increasing the heating temperature of the thermal catalyst heating unit per cumulative time of the substrate processing or per number of substrates processed.

A maintenance method of a substrate processing apparatus of the present disclosure performs a maintenance of a substrate processing apparatus which includes a processing container provided therein with a placing unit configured to place a processing target substrate thereon, a substrate heating unit configured to heat the processing target substrate placed on the placing unit, an exhaust passage configured to exhaust the atmosphere inside the processing container, a light source unit configured to irradiate light to the substrate placed on the placing unit, and a light transmission window configured to partition the light source unit and the atmosphere inside the processing container. The maintenance method includes carrying, into the processing container, a maintenance substrate provided with a thermal catalytic material to be heated and therefore thermally activated to decompose a sublimate as a product generated from the processing target substrate by the processing of the processing target substrate, heating the maintenance substrate by the substrate heating unit in order to thermally activate the thermal catalytic material, and causing the heated maintenance substrate to approach the light transmission window in order to remove the sublimate attached to the light transmission window.

A non-transitory computer-readable storage medium of the present disclosure stores a computer program used for a substrate processing apparatus including a processing container provided therein with a placing unit configured to place a processing target substrate thereon. The computer program includes a step group organized to, when executed, cause a computer to execute the above-described substrate processing method.

The non-transitory computer-readable storage medium of the present disclosure stores a computer program used for a substrate processing apparatus including a processing container provided therein with a placing unit configured to place a processing target substrate thereon. The computer program includes a step group organized to, when executed, cause a computer to execute the above-described maintenance method of the substrate processing apparatus.

According to the present disclosure, in processing the substrate inside the processing container and exhausting the atmosphere inside the processing container, the thermal catalytic material is provided in at least one of the inner surface of the processing container and the exhaust passage, and when the thermal catalytic material is heated, a product generated in the atmosphere inside the processing container is decomposed and removed. Hence, the product may be suppressed from being attached to the exhaust passage, thereby reducing the maintenance frequency.

According to another exemplary embodiment of the present disclosure, in processing the substrate by light from the light source unit while exhausting the inside of the processing container, the maintenance substrate provided with the thermal catalytic material is heated and caused to approach the light transmission window so as to remove the sublimate attached to the light transmission window. Thus, it is possible to clean the light transmission window without disassembling the processing container.

### First Exemplary Embodiment

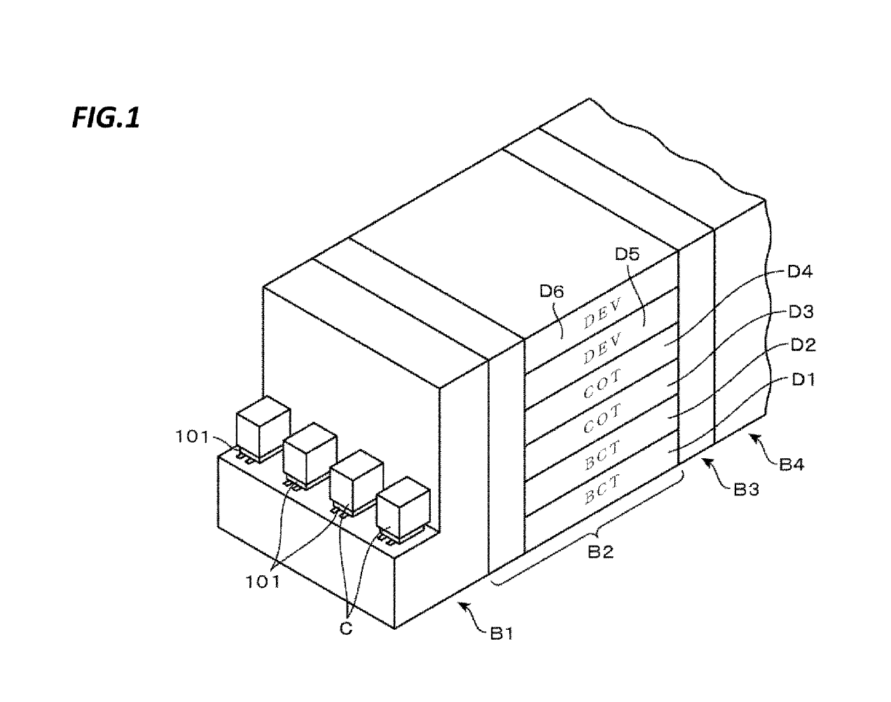

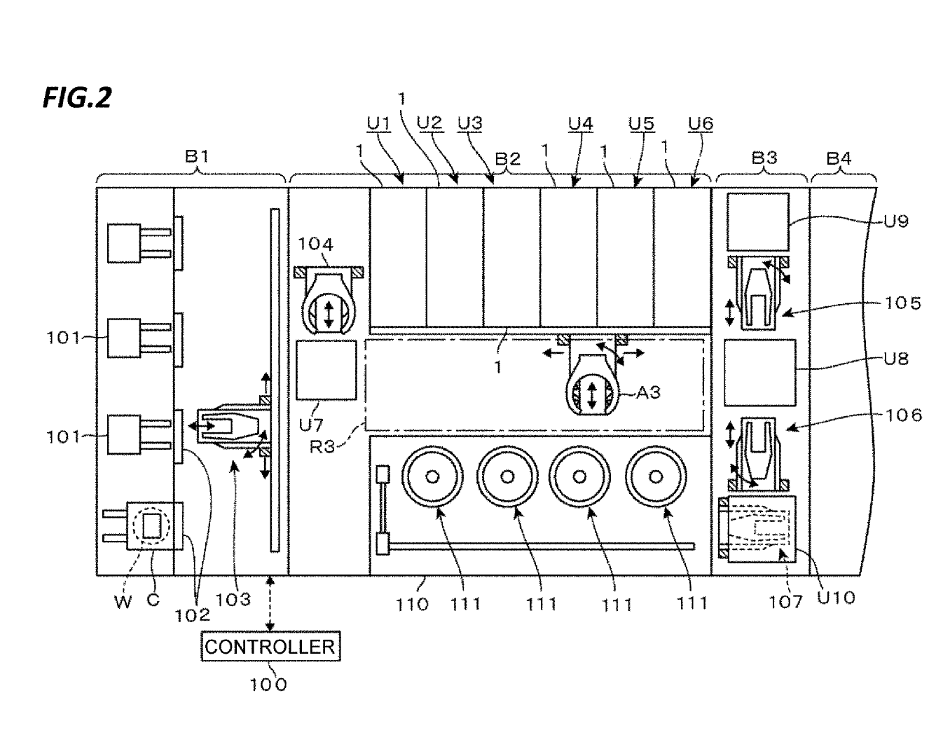

Descriptions will be made on an example where a substrate processing apparatus according to a first exemplary embodiment of the present disclosure is applied to a heating processing apparatus. First, brief descriptions will be made on an entire coating/developing apparatus as a substrate processing system into which the heating processing apparatus of the present disclosure is incorporated. As illustrated in FIGS. 1 and 2, the coating/developing apparatus is configured by a carrier block B1, a processing block B2, and an interface block B3 which are linearly connected to each other. In addition, an exposure station B4 is connected to the interface block B3.

The carrier block B1 has a function to carry, into and out from the apparatus, wafers W from a carrier C (e.g., a front opening unified pod (FOUP)) which is a conveyance container accommodating a plurality of wafers W each having a diameter of, for example, 300 mm as product substrates. The carrier block B1 includes a placing stage 101 for a carrier C, a door 102, and a conveyance arm 103 configured to convey a wafer W from the carrier C.

The processing block B2 is configured such that first to sixth unit blocks D1 to D6 configured to perform a liquid processing on a wafer W are stacked in this order from the bottom. The unit blocks D1 to D6 are substantially identical to each other in configuration. In FIG. 1, the alphabets written on the respective unit blocks D1 to D6 represent processing types. BCT represents an antireflection film forming processing. COT represents a resist film forming processing that forms a resist film on a wafer W by supplying a resist thereto. DEF represents a development processing.

FIG. 2 illustrates the configuration of the unit block D3 among the unit blocks D1 to D6. The unit block D3 is provided with a main arm A3 that moves in a linear conveyance region R3 directed from the carrier block B1 side toward the interface block B3, and a coating unit 110 including cup modules 111. In addition, a heating module, which corresponds to the heating processing apparatus of the present disclosure, and a cooling module 1 are stacked on each of shelf units U1 to U6.

A shelf unit U7 is provided at the carrier block B1 side of the conveyance region R3 and configured by a plurality of modules stacked on one another. Transfer of a wafer W between the conveyance arm 103 and the main arm A3 is performed through a transfer module and a conveyance arm 104 of the shelf unit U7.

The interface block B3 is configured to transfer a wafer W between the processing block B2 and the exposure station B4, and includes shelf units U 8, U9, and U10 each provided with a plurality of processing modules stacked on one another. In addition, in FIG. 2, the reference numerals 105 and 106 represent conveyance arms configured to transfer a wafer W between the shelf units U8 and U9 and between the shelf units U9 and U10, respectively, and the reference numeral 107 represents a conveyance arm configured to transfer a wafer W between the shelf unit U10 and the exposure station B4.

An outline of the conveyance route of a wafer W in the system provided with the coating/developing apparatus and the exposure station B4 will be briefly described. A wafer W is conveyed along the following route: the carrier C→ the conveyance arm 103→ the transfer module of the shelf unit U7→ the conveyance arm 104→ the transfer module of the shelf unit U7→ the unit blocks D1 and D2→ the unit blocks D3 and D4→ the interface block B3→ the exposure station B4→ the interface block B3→ the unit blocks D5 and D6→ the transfer module TRS of the shelf unit U7→ the conveyance arm 103→ the carrier C.

As illustrated in FIG. 2, the coating/developing apparatus includes a controller 100. The controller 100 includes a program storing unit. The program storing unit stores the wafer conveyance recipe and a program including commands organized to implement the sequences in the work of cleaning each heating module and each cooling module.

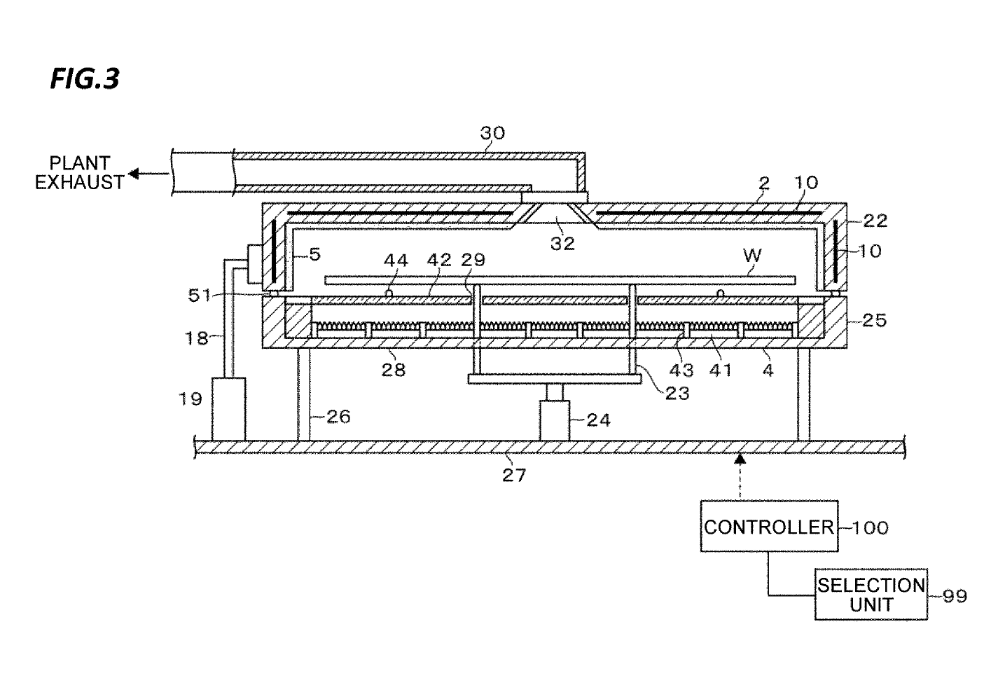

FIG. 3 illustrates the entire configuration of the heating processing apparatus as the heating module. In FIG. 3, the reference numeral 2 represents a processing container. The processing container 2 is formed by a lower member 25 in a top-opened flat cylinder shape, and a cover 22 configured to move up and down with respect to the lower member 25 so as to open/close the processing container 2. The processing container 2 serves as a heating chamber where a heating processing is performed on a 300 mm-diameter wafer W as a substrate. The lower member 25 is supported on a base mount 27, which corresponds to the bottom portion of a housing (not illustrated) serving as the exterior body of the heating processing apparatus, through a support member 26. A LED array 41 is provided in the lower member 25 to serve as a light source unit which is the substrate heating unit, and a light transmission window 42 made of, for example, quartz is provided above the LED array 41 to partition the atmosphere where the LED array 41 is disposed and the processing atmosphere. The entire circumference of the LED array 41 is surrounded by a reflection plate 43 formed by plating, for example, a copper (Cu) plate with gold. Thus, light directed toward a direction different from the irradiation direction (the upward direction in FIG. 3) is reflected so that the radiation light may be effectively irradiated. In addition, a projection 44 is formed on the front surface of the light transmission window 42 to hold a cleaning substrate to be described later in a state of approaching the light transmission window 42.

Through holes 29 are formed at three points in the bottom portion 28 of the lower member 25 and the light transmission window 42 with a circumferentially equal interval when viewed from the top side, to penetrate through the bottom portion 28 of the lower member 25 and the light transmission window 42 in the thickness direction thereof. Lift pins 23 are provided to correspond to the through holes 29, respectively, so as to support a wafer W. The lift pins 23 are configured to move up and down by a lift mechanism 24 provided on the base mount 27 so as to project and retract from the front surface of the light transmission window 42. When the wafer W is moved up and down, the wafer W is transferred between the lift pins 23 and, for example, the main arm A3 in FIG. 2.

The cover 22 is formed in a bottom-opened flat cylinder shape, and configured to be movable up and down between a downward-movement position where the cover 22 contacts the top side of the peripheral wall of the lower member 25 (specifically, pins 51 to be described later) so as to close the processing container 2, and an upward-movement position where the wafer W is transferred to/from the lift pins 23. In this example, the up-and-down movement of the cover 22 is performed when a lift arm 18 attached to the outer peripheral surface of the cover 22 is driven by the lift mechanism 19 provided on the base mount 27.

In addition, the pins 51 are formed circumferentially with an interval on the top surface of the peripheral wall of the lower member 25, and have a height of, for example, 1 mm. Accordingly, a 1 mm gap is formed between the cover 22 and the lower member 25 when the cover 22 is closed. Thus, when the inside of the processing container 2 is exhausted, outside air (the atmosphere of the clean room where the heating processing apparatus is disposed) is introduced from the gap to form an air current inside the processing container 2.

An exhaust port 32 is formed at the center of the ceiling plate of the cover 22. The bottom portion of one end side of an exhaust passage 30 serving as an exhaust duct is connected to the exhaust port 32. The exhaust passage 30 radially and linearly extends along the top surface of the cover 22 to be connected to an exhaust duct within a plant.

In addition, a thermal catalytic layer 5 is provided on the entire inner wall of the processing container 2 and formed by coating a thermal catalytic material (thermal catalyst) composed of, for example, Cr₂O₃ thereon. The thermal catalytic layer 5 may be provided by forming a film of a thermal catalyst on, for example, a substrate through an already known coating technique such as, for example, application or spraying. A heater 10 is embedded in the wall of the cover 22 to serve as a thermal catalyst heating unit that heats the thermal catalytic layer 5 inside the processing container 2. The calorific value of the heater 10 is set to a temperature at which the thermal catalytic layer 5 is thermally activated to function as the thermal catalyst, that is, a temperature at which the thermal catalytic layer 5 implements the function to thermally decompose a sublimate generated from the wafer W to reach the vicinity of the thermal catalytic layer 5, e.g., 200° C. to 400° C. for Cr₂O₃. The exhaust passage 30 disposed on the top surface of the cover 22 is heated by a heater (not illustrated) to a temperature at which the sublimate generated from the wafer W is not attached to the exhaust passage 30.

FIG. 3 illustrates a controller that controls the heating processing apparatus. Since the controller may be a part of the controller illustrated in FIG. 1, the controller will be denoted by the same reference numeral 100. In FIG. 3, a selection unit 99 is connected to the controller 100 to select a maintenance mode so that when the maintenance mode is selected, a program for performing the maintenance of the heating processing apparatus is started.

This selection unit 99 is provided in, for example, an operation panel operated by an operator. The controller 100 controls the up-and-down movement of the lift pins 23 by the lift mechanism 24 and an intensity regulation of irradiation by a LED module 4 or an on/off operation thereof based on, for example, an operation program input in advance in the controller 100.

Subsequently, descriptions will be made on the operation of the heating processing apparatus which is the substrate processing apparatus of the present exemplary embodiment. First, a wafer W is carried into the processing container 2 by an outside conveyance arm, e.g., the main arm A3 illustrated in FIG. 2. At this time, the LED module 4 is in the OFF state. When the wafer W held on the main arm A3 reaches above the light transmission window 42, the lift pins 23 are moved up by the lift mechanism 24 to push up the wafer W on the main arm A3 and receive the wafer W from the main arm A3, and the main arm A3 that has transferred the wafer W retreats to the outside of the processing container 2.

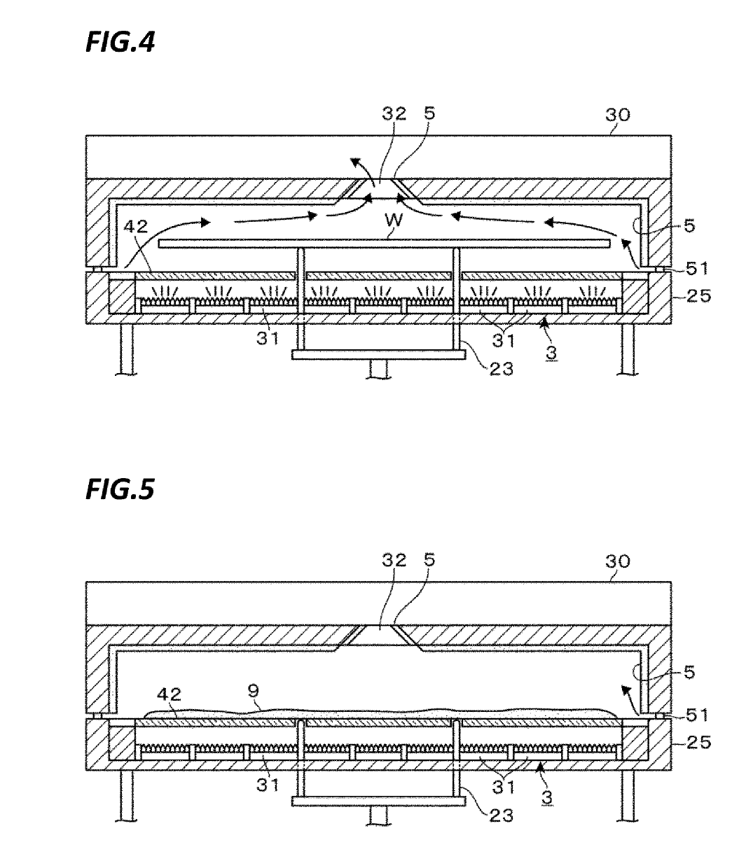

Then, the cover 22 is moved down to form the processing atmosphere in the state where the cover 22 is closed as illustrated in FIG. 3, and the lift pins 23 are moved down to place the wafer W at a position with a predetermined height, for example, at a position where the height of the gap between the front surface of the light transmission window 42 and the rear surface of the wafer W is 3 mm Subsequently, infrared light, which is radiation light having an absorption wavelength region of the wafer W, is irradiated from the LED module 4 toward the wafer W so that the wafer W is heated to a predetermined heating processing temperature of 200° C. to 400° C., for example, 300° C. In the present exemplary embodiment, the lift pins 23 correspond to the placing unit. In addition, for example, after the cover 22 is moved down, exhausting the inside of the processing container 2 is started through the exhaust passage 30. As described above, a gap is formed between the cover 22 and the lower member 25 due to the existence of the pins 51 in the state in which the cover 22 is closed. Hence, when the inside of the processing container 2 becomes a negative pressure, the ambient atmosphere (air) is introduced from the gap so that, as illustrated in FIG. 4, an air current directed from the outer periphery of the processing container 2 toward the central upper portion thereof is formed inside the processing container 2.

In this case, for example, an organic component contained in a coating liquid is sublimated from the coating film of the wafer W to become a sublimate. The sublimate as a product is likely to be carried along with the air current formed inside the processing container 2 to flow toward the exhaust port 32 at the central upper portion of the processing container 2 and enter into the exhaust passage 30 from the exhaust port 32. Meanwhile, since the thermal catalytic layer 5 formed on the inner wall surface of the processing container 2 including the ceiling surface thereof is thermally activated by the heater 10, the sublimate approaching the vicinity of the inner wall surface of the processing container 2 is decomposed by the thermo-catalysis of the thermal catalytic layer 5.

Here, descriptions will be made on the decomposition of the product generated at the time of processing the wafer W with the thermal catalytic layer 5, that is, the sublimate sublimated from the coating film. When the thermal catalytic layer 5, e.g., Cr₂O₃ is heated, electrons are excited so that the thermal catalytic layer 5 has a strong oxidizing power. When the sublimate as an organic component approaches the thermal catalytic layer 5, the organic component is oxidized to generate radicals within the sublimate. Thereafter, the generated radicals propagate inside the sublimate at 200° C. to 400° C. Then, the sublimate is cleaved by the radicals into small molecules, and the sublimate cleaved into small molecules is combined with oxygen contained in the atmosphere inside the processing container 2 to change into carbon dioxide and water.

Hence, the atmosphere inside the processing container 2 which is to be exhausted from the exhaust port 32 is exhausted after the sublimate is decomposed by the catalysis of the thermal catalytic layer 5.

When the heating processing is ended, the lift pins 23 move up to push up the wafer W, and continue to move up to the transfer height position with respect to the main arm A3. Then, after the main arm A3 is caused to approach the transfer position of the wafer W inside the processing container 2, the lift pins 23 move down to transfer the wafer W to the main arm A3. The main arm A3 that has received the wafer W retreats in the state of holding the wafer W to carry the wafer W to the outside of the processing container 2.

In this way, the sublimate sublimated from the wafer W is decomposed by the thermal catalytic layer 5 coated on the inner wall surface of the processing container 2 and thereafter exhausted. However, a part of the sublimate enters into the gap between the wafer W and the light transmission window 42 to be attached to the front surface of the light transmission window 42. Hence, as illustrated in FIG. 5, the sublimate 9 is precipitated on the front surface of the light transmission window 42 so that the transmittance of the light to be irradiated from the LED module 3 is deteriorated. As a result, temperature irregularity of the wafer W occurs so that the heating may not be favorably implemented, and furthermore, the sublimate 9 may be a particle generation source.

Accordingly, the heating processing apparatus performs a cleaning work to remove the sublimate 9 precipitated on the front surface of the light transmission window 42, for example, after finishing the processing of a preset number of wafers W. This cleaning work uses a cleaning substrate which is obtained by coating the rear surface of a wafer W with a diameter of, for example, 300 mm with the thermal catalytic layer 5. To describe the removal of the sublimate using the cleaning substrate, an operator first selects the maintenance mode by the mode selection unit 99. By this selection, the cleaning substrate is taken out by the conveyance arm 103 from the carrier C disposed in the carrier block B1 of the coating/developing apparatus illustrated in FIGS. 1 and 2. The cleaning substrate is transferred to the main arm A3 through the conveyance arm 104 and the shelf unit U7. Then, the cleaning substrate is carried into the processing container 2 by the main arm A3 to be transferred to the lift pins 23.

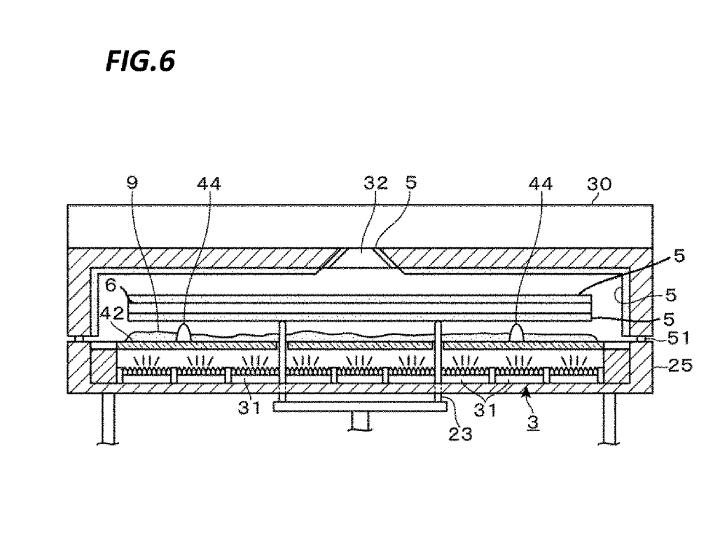

Thereafter, as illustrated in FIG. 6, the lift pins 23 are moved down to transfer (place) the cleaning substrate 6 to (on) the projection 44 group. Then, the exhaust from the exhaust passage 30 is started, and the LED module 3 is turned on to heat the cleaning substrate 6 to, for example, 300° C. Accordingly, it is understood that the LED module 4 serves as both the thermal catalyst heating unit and the substrate heating unit. Then, the thermal catalytic layer 5 on the rear surface of the cleaning substrate 6 is activated so that the sublimate 9 attached to the light transmission window 42 is decomposed and removed by the thermal catalysis since the distance between the light transmission window 42 and the cleaning substrate 6 is as close as about 3 mm. The decomposed component of the sublimate 9 is exhausted from the exhaust passage 30 along with the atmosphere inside the processing container 2.

In addition, the cleaning substrate 6 may be disposed in a depository inside the coating/developing apparatus. As the depository, for example, a part of the shelf unit U7 may be used.

In the first exemplary embodiment, in performing the heating processing of the wafer W inside the processing container 2, the thermal catalytic layer 5 is formed on the inner surface of the processing container 2 and heated. Thus, when the sublimate sublimated from the coating film on the wafer W and received within the processing container 2 reaches the vicinity of the thermal catalytic layer 5, the sublimate is decomposed and removed by the thermal activation of the thermal catalytic layer 5. As a result, since the amount of the sublimate to be introduced into the downstream side of the exhaust passage 30 is reduced, the amount of the sublimate to be attached to the exhaust passage 30 is reduced so that the maintenance frequency may be reduced. At the same time, since the precipitation of the sublimate on the inner surface of the processing container 2 is suppressed, a particle contamination may be reduced, and the frequency to clean the inside of the processing container 2 may be also reduced.

In addition, when the cleaning substrate 6 formed with the thermal catalytic layer 5 on the rear surface thereof is carried into the processing container 2 and heated, the sublimate 9 attached to the front surface of the light transmission window 42 is removed. As a result, it is possible to reduce the frequency of the maintenance to clean the inside of the processing container 2 by disassembling the processing container 2.

### Second Exemplary Embodiment

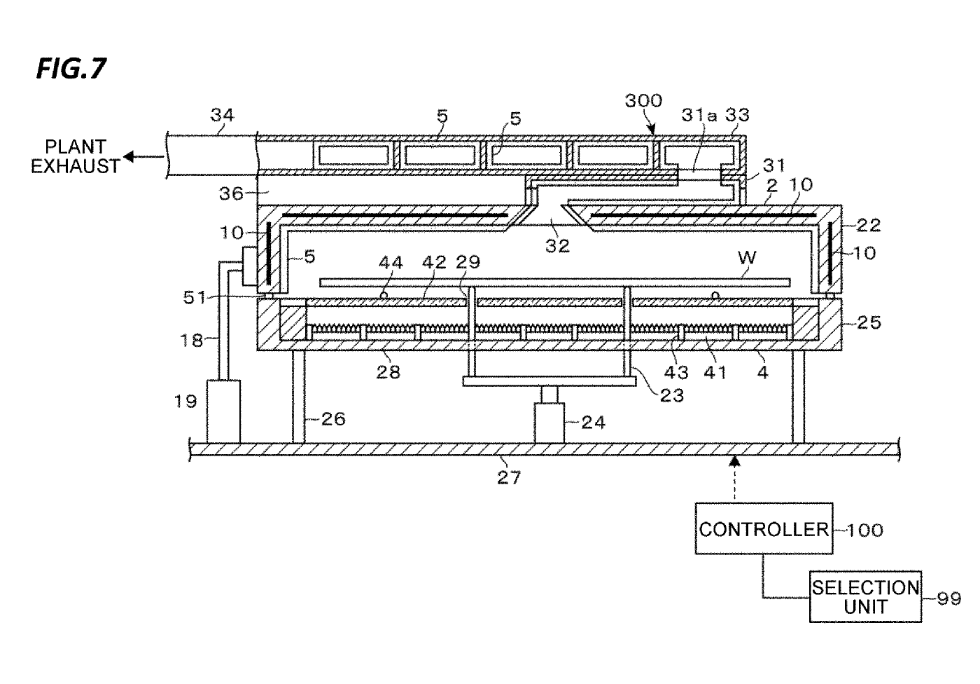

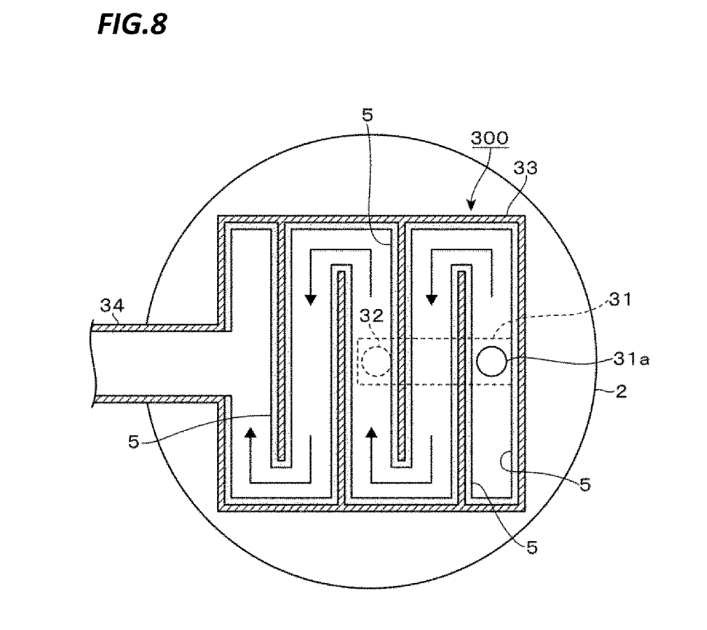

FIGS. 7 and 8 illustrate a substrate processing apparatus according to a second exemplary embodiment. This substrate processing apparatus is configured such that, in the heating processing apparatus illustrated in FIG. 3, the portion of the exhaust passage 30 which is disposed above the processing container 2 has, for example, a maze structure to make the pressure loss therein larger than the pressure loss in the further downstream side portion of the exhaust passage 30. The thermal catalytic layer 5 is formed in the portion having the maze structure. In this example, the further downstream side portion corresponds to an exhaust pipe 34 which serves as the exhaust passage disposed at the downstream side in comparison with the portion disposed above the processing container 2. The maze portion corresponds to the pressure loss section (pressure loss unit) and will be described as an exhaust passage 300 for convenience of descriptions.

The exhaust passage 300 includes a lower exhaust passage 31 and an upper exhaust passage 33. The lower exhaust passage 31 is connected to the exhaust port 32 at one end side thereof and extends toward the right peripheral edge of the processing container 2 in FIG. 7. The upper exhaust passage 33 is provided above the lower exhaust passage 31 and has the bottom surface communicating with the other end side of the lower exhaust passage 31 through a communication port 31a. The upper exhaust passage 33 is curved several times to left and right directions toward the left peripheral edge of the processing container to be connected to the exhaust pipe 34 connected to a so-called plant exhaust (an exhaust duct routed inside a plant). In addition, the thermal catalytic layer 5 is formed on the inner surface of each of the lower exhaust passage 31 and the upper exhaust passage 33. In addition, a heat transfer plate 36 is provided between the upper exhaust passage 33 and the processing container 2 to transfer the heat from the heater 10 provided in the processing container 2 thereby heating the thermal catalytic layer 5 to, for example, 300° C. In addition, a heater dedicated to heat the exhaust passage 300 may be provided.

In the second exemplary embodiment, when the atmosphere inside the processing container 2 is introduced into the exhaust passage 300 through the exhaust port 32, the sublimate is decomposed by the thermal catalytic layer 5 and exhausted while the atmosphere flows through the exhaust passage 300. In addition, since the flow passage of the exhaust passage 300 is curved, the pressure loss in the exhaust passage 300 is larger than the pressure loss in an exhaust pipe having an exhaust passage formed by an ordinary layout, i.e., the exhaust pipe 34 at the downstream side. This increases the likelihood that the exhaust flow as the atmosphere inside the processing container 2 collides with the inner wall of the exhaust passage 300. Hence, the time duration that the sublimate contained in the exhaust flow contacts the thermal catalytic layer 5 or stays in the vicinity of the thermal catalytic layer 5 is prolonged, so that the sublimate may be more reliably removed. As a result, the amount of the sublimate to be attached to the exhaust pipe 34 may be reduced thereby lowering the maintenance frequency.

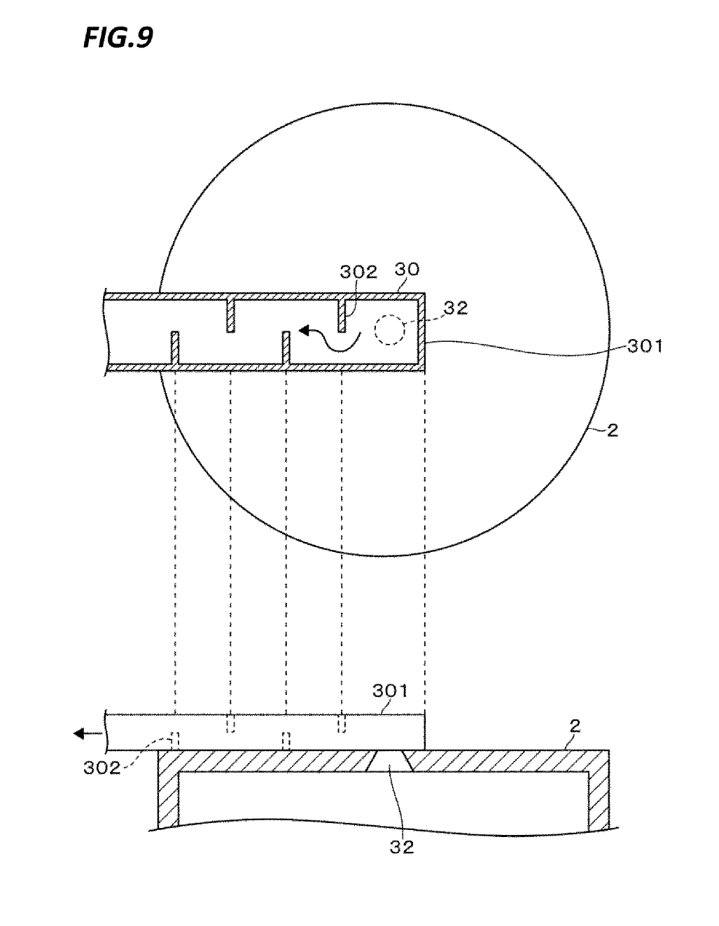

FIG. 9 illustrates another example of the shape and the structure of the exhaust passage as the pressure loss unit. As illustrated in FIG. 9, the exhaust passage 301 as the pressure loss unit is connected to the exhaust port 32 of the processing container 2 at the bottom surface of one end side thereof, and extends linearly toward the other end side thereof. In addition, when viewed in the longitudinal direction of the exhaust passage 301, a capturing plate unit 302 extends from the right side wall toward the left side wall and simultaneously extends from the ceiling surface toward the bottom surface, and another capturing plate unit 302 extends from the left side wall toward the right side wall and simultaneously extends from the bottom surface toward the ceiling surface. The capturing plate units 302 are alternately arranged side by side in the longitudinal direction of the exhaust passage 301. The thermal catalytic layer 5 is formed on the inner surface of the exhaust passage 301 and the surfaces of the capturing plate units 302.

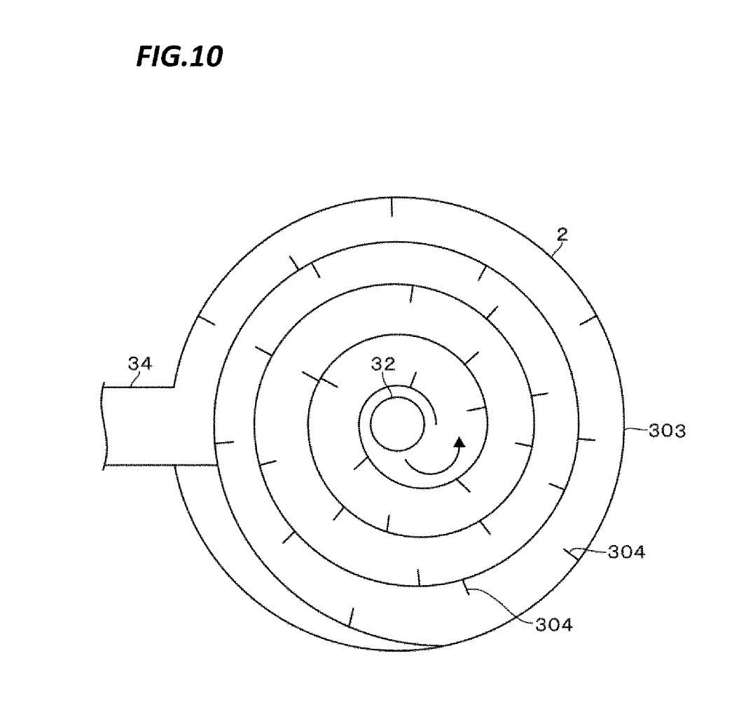

In addition, as illustrated in FIG. 10, the exhaust passage as the pressure loss unit may be an exhaust passage 303 configured to be connected to the exhaust port 32 at the bottom surface of one end side thereof and routed outwardly and spirally such that the outer edge of the exhaust passage 303 is connected to the exhaust pipe 34. In this case, as illustrated in, for example, FIG. 10, the exhaust passage 303 may be configured such that capturing plate units 304 alternately project from the left and right side walls when viewed in the direction of the exhaust flow.

Although it is preferable that the exhaust passage causing the large pressure loss is provided immediately at the downstream side of the processing container 2, and the thermal catalytic layer 5 is formed in the exhaust passage, the thermal catalytic layer 5 may be provided in the exhaust passage 30 that follows the ordinary layout. In this case as well, the effect in suppressing the sublimate attachment to the exhaust passage at the downstream side can be achieved.

In the above-described exemplary embodiments, the LED array 41 is used as the substrate heating unit configured to heat the wafer W. However, the substrate heating unit may be a heating plate which places the wafer W thereon and is heated by a heater.

### Third Exemplary Embodiment

Descriptions will be made on an example where a substrate processing apparatus according to a third exemplary embodiment of the present disclosure is applied to an apparatus which performs a UV processing on a wafer W by irradiating ultraviolet (UV) rays onto the surface of the wafer W, e.g., a UV processing apparatus which planarizes a surface of a coating film formed on a wafer W.

The coating film may be, for example, a SOC film formed on a pattern of a wafer W. A raw material used for the SOC film is a liquid obtained by dissolving, in a solvent, an organic film material, which contains a carbon compound to be decomposed by a reaction with active oxygen or ozone generated by irradiation of ultraviolet rays under an oxygen-containing atmosphere, e.g., a polymer material having the skeleton of the polyethylene structure ((—CH₂—)ₙ).

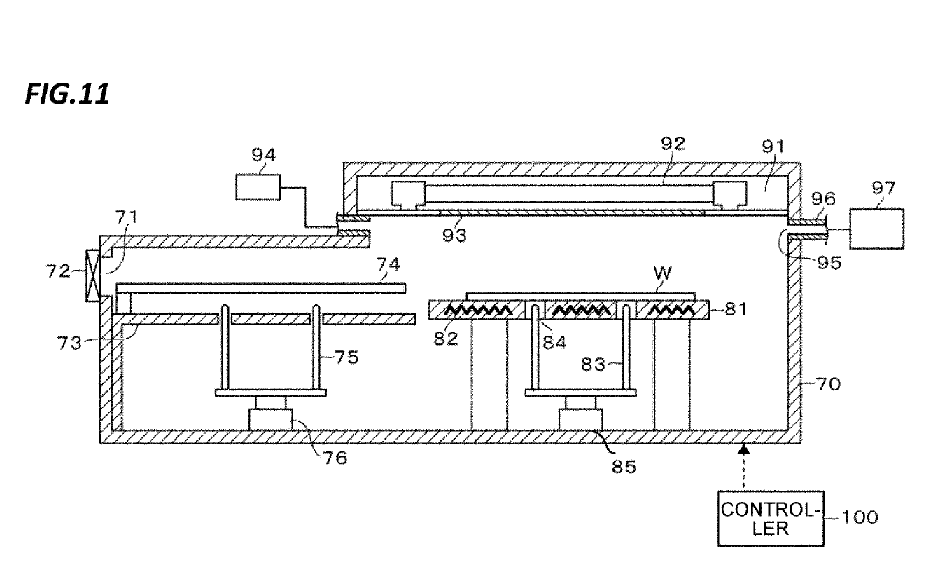

As illustrated in FIG. 11, the UV processing apparatus includes a flat cuboid housing 70 that is long and narrow in the front-and-rear direction. A carry in/out port 71 and a shutter 72 are provided in the front side wall of the housing 70. The carry in/out port 71 carries a wafer W into/out from the housing 70, and the shutter 72 opens and closes the carry in/out port 71.

In the inside of the housing 70, a conveyance arm 74 configured to convey a wafer W is provided in the space above a partition plate 73 in the front side of the housing 70 when viewed from the carry in/out port 71. The conveyance arm 74 is provided with a moving mechanism (not illustrated) configured to move in the front-and-rear direction between the front side position for transferring a wafer W with respect to an outside conveyance arm (not illustrated) and the rear side position for transferring a wafer W with respect to a placing table 81 to be described later. The conveyance arm 74 also acts as a cooling arm that cools a processed wafer W.

Lift pins 75 are provided in the front side position for transferring a wafer W with respect to an outside conveyance arm and configured to temporarily support the wafer W when the wafer W is transferred between the outside conveyance arm and the conveyance arm 74. The lift pins 75 are connected to a lift mechanism 76 provided in the space below the partition plate 73, and configured to be movable up and down between a position lower than the placing surface of the conveyance arm 74 that places the wafer W thereon and the position higher than the placing surface of the conveyance arm 74 to transfer a wafer W with respect to the outside conveyance arm.

The placing table 81 of a wafer W is disposed at the rear side of the position where the conveyance arm 74 transfers a wafer W with respect to the outside conveyance arm. A heater 82 is embedded in the placing table 81, and also has the function of the heating unit to heat a wafer W.

Lift pins 83 are provided below the placing table 81 to temporarily support a wafer W when the wafer W is transferred with respect to the conveyance arm 74. As illustrated in FIG. 5, through holes 84 are formed in the placing table 81 to allow the lift pins 83 to penetrate therethrough.

The lift pins 83 are connected to a lift mechanism 85, and move up and down between a position below the placing surface of the conveyance arm 74 that places the wafer W thereon when the conveyance arm 74 moves up to the upper side of the placing table 81 and a position above the placing surface, to transfer the wafer W with respect to the conveyance arm 74 and place the wafer W on the placing table 81. In addition, the lift pins 83 are configured such that, when supporting the cleaning substrate 6 described in the first exemplary embodiment, the lift pins 83 can move up to the position where the height dimension between the front surface of the cleaning substrate 6 and the ceiling surface (specifically, the rear surface of a UV transmission unit 93 to be described later) is within a range of several mm to ten or more mm, e g, 3 mm.

A lamp chamber 91 is provided above the placing table 81 and configured to accommodate a UV lamp 92 which is a light source unit that irradiates UV rays onto the wafer W placed on the placing table 81. The UV transmission unit 93 is provided in the bottom surface of the lamp chamber 91 and serves as a light transmission window that transmits UV rays irradiated from the UV lamp 92 toward the wafer W. The UV transmission unit 93 is formed of, for example, quartz transmitting UV rays.

In addition, a gas supply unit 94 and an exhaust port 95 are formed opposite to each other at the side walls of the housing 70 below the lamp chamber 91. The gas supply unit 94 is configured to supply clean air into the housing 70, and the exhaust port 95 is configured to exhaust the atmosphere inside the housing 70. An exhaust mechanism 97 is connected to the exhaust port 95 through an exhaust pipe 96.

In addition, as in the heating processing apparatus, the controller 100 is connected to the UV processing apparatus.

In the UV processing apparatus, the wafer W coated with the SOC film on the surface thereof is transferred to the conveyance arm 74 by the cooperation between an outside substrate conveyance mechanism and the lift pins 75. Subsequently, when the conveyance arm 74 moves to the position above the placing table 81 and stops there, the lift pins 83 move up so that the wafer W is transferred from the conveyance arm 74 to the lift pins 83. Thereafter, the lift pins 83 move down to place the wafer W on the placing table 81. Then, a gas is supplied from the gas supply unit 94, and the exhaust from the exhaust port 95 is started.

Thereafter, the wafer W is heated to, for example, 250° C., and the UV lamp 72 is turned on to irradiate UV rays. By the irradiated UV rays, active oxygen or ozone is generated from the oxygen in the clean air (the oxygen-containing atmosphere) above the wafer W. By the active oxygen or the ozone, the surface of the SOC film (a part of the SOC film) is decomposed and removed so that so-called etchback is performed.

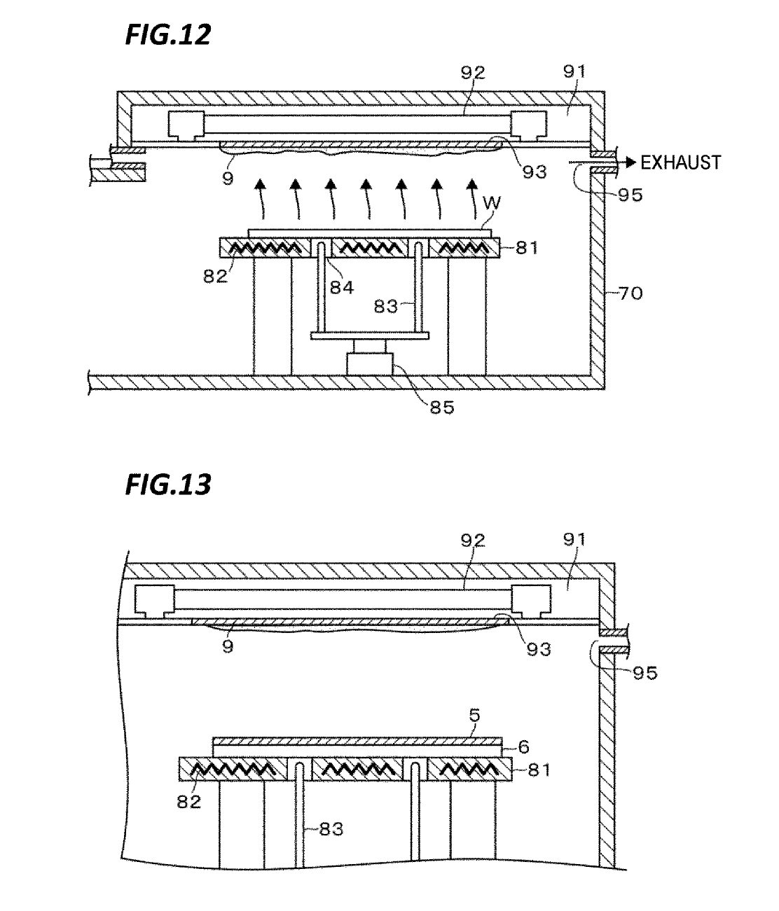

In planarizing the SOC film by irradiating UV onto the wafer W, as illustrated in FIG. 12, the sublimate, which has been sublimated from the wafer W when the wafer W has been subject to the heating processing, may be attached to the rear surface of the UV transmission unit 93. When the sublimate 9 is attached to the UV transmission unit 93, the transmittance of the UV transmission unit 93 is deteriorated so that the UV processing may not be favorably performed. Thus, for example, after a preset number of wafers W are processed, the sublimate 9 is removed by using the cleaning substrate 6 formed with the thermal catalytic layer 5 over the entire surface of at least one of the front and rear surfaces thereof.

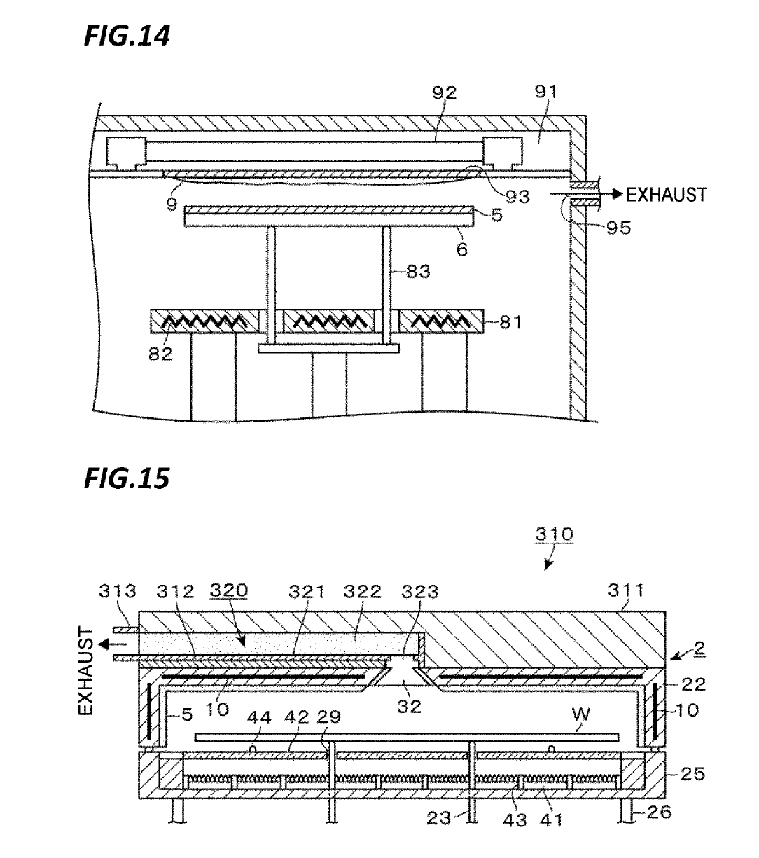

The cleaning substrate 6 is placed on the placing table 81, for example, according to the same process as that for the wafer W as illustrated in FIG. 13. Thereafter, the cleaning substrate 6 (the thermal catalytic layer 5) is heated to 200° C. to 400° C., for example, 300° C., by the placing table 81. Subsequently, as illustrated in FIG. 14, the lift pins 83 move up to elevate the cleaning substrate 6 to the position where the height dimension between the cleaning substrate 6 and the UV transmission unit 93 is within a range of several mm to ten or more mm, e g, 3 mm. At this time, the heating by the placing table 81 is continued such that the temperature of the cleaning substrate 6 is kept at 300° C. In addition, clean air is supplied by the gas supply unit 94, and the exhaust from the exhaust port 95 is started. As a result, the sublimate 9 attached to the rear surface of the UV transmission unit 93 is decomposed by the action of the thermal catalytic layer 5, and the decomposed sublimate 9 is exhausted from the exhaust port 95 along with the atmosphere.

According to the third exemplary embodiment, the sublimate 9 attached to the rear surface of the UV transmission unit 93 is removed by heating the cleaning substrate 6. Accordingly, it is possible to suppress the adverse effect on the UV processing arising from the deterioration of the UV transmission. Also, it is possible to achieve the effect in reducing the frequency of the maintenance that cleans the inside of the processing container 2 by disassembling the processing container 2.

In the third exemplary embodiment, the thermal catalytic layer may also be formed in the exhaust pipe 96 to suppress precipitation of a sublimate in the downstream side exhaust passage. In this case, the exhaust pipe 96 may have the structure causing the large pressure loss as in the second exemplary embodiment.

In addition, the placing table 81 may be configured to be freely movable up and down such that the placing table 81 moves up to cause a removal dedicated substrate to approach the rear surface of the UV transmission unit 93. In this example, at least the front surface of the cleaning substrate 6 is coated with the thermal catalytic layer 5, but both the front and rear surfaces of the cleaning substrate 6 may be coated.

The substrate processing apparatus of the present disclosure is not limited to an apparatus for heating a substrate and may be, for example, an apparatus for etching a substrate with a processing gas.

Examples of the material used for the thermal catalytic layer may include materials represented by the following chemical formulas: BeO (beryllium oxide), MgO (magnesium oxide), CaO (calcium oxide), SrO (strontium oxide), BaO (barium oxide), CeO₂ (cerium oxide), TiO₂ (titanium oxide), ZrO₂ (zirconium dioxide), V₂O₅ (divanadium pentoxide), Y₂O₃ (yttrium oxide), Y₂O₂S (yttrium oxide sulfide), Nb₂O₅ (diniobium pentoxide), Ta₂O₅ (tantalum pentoxide), MoO₃ (molybdenum trioxide), WO₃ (tungsten trioxide), MnO₂ (manganese dioxide), Fe₂O₃ (diiron trioxide), Fe₃O₄ (triiron tetroxide), MgFe₂O₄, NiFe₂O₄, ZnFe₂O₄, ZnCo₂O₄, ZnO (zinc oxide), CdO (cadmium oxide), MgAl₂O₄, ZnAl₂O₄, Tl₂O₃ (thallium oxide), In₂O₃ (indium oxide), SnO₂ (tin dioxide), PbO₂ (lead dioxide), UO₂ (uranium dioxide), Cr₂O₃ (nichrome trioxide), MgCr₂O₄, FeCrO₄, CoCrO₄, ZnCr₂O₄, WO₂ (tungsten oxide), MnO (manganese oxide), Mn₃O₄ (trimanganese tetraoxide), Mn₂O₃ (dimanganese trioxide), FeO (iron dioxide), NiO (nickel oxide), CoO (cobalt oxide), Co₃O₄ (tricobalt tetraoxide), PdO (palladium oxide), CuO (copper oxide), Cu₂O (copper dioxide), Ag₂O (silver oxide), CoAl₂O₄, NiAl₂O₄, Ti₂O (titanium oxide), GeO (germanium oxide), PbO (lead oxide), TiO (titanium oxide), Ti₂O₃ (dititanium trioxide), VO (vanadium oxide), MoO₂ (molybdenum dioxide), IrO₂ (iridium dioxide), RuO₂ (ruthenium oxide). In addition, these thermal catalysts may be heated to a temperature of 200° C. or higher, more preferably, 300° C. or higher.

In addition, in providing a thermal catalyst in the inner surface of the processing container or the exhaust pipe, for example, a molding body obtained by molding a thermal catalyst in a plate shape may be provided therein. In addition, the maintenance substrate may be a plate-shaped body made of a thermal catalyst.

In addition, when these materials are used for the thermal catalytic layer 5, it is possible to decompose, for example, polyethylene terephthalate, polypropylene, polyvinyl chloride, polystyrene, an ABS resin, an epoxy resin, phenol residues, benzene, toluene, and a volatile organic carbon.

In coating the thermal catalytic layer on the inner surface of the processing container or the exhaust pipe, a cooling mechanism configured to cool the thermal catalytic layer may be provided together with the heating unit configured to heat the thermal catalytic layer. For example, a cooling pipe may be embedded in the wall of the processing container or around the exhaust pipe to allow cooling water cooled by, for example, a chiller to flow through the cooling pipe. In this configuration, for example, the thermal catalytic layer is cooled by the cooling mechanism so that an organic component contained in the atmosphere inside the processing container or the exhaust flowing through the exhaust pipe is precipitated on the surface of the thermal catalytic layer. Then, the thermal catalytic layer is heated by the heating mechanism to decompose and remove the sublimate. According to this technique, since the organic component contained in the atmosphere or the exhaust may be actively collected by cooling the thermal catalytic layer, the collecting efficiency increases so that more sublimates may be removed than those when the organic component is removed by heating the thermal catalytic layer. Thus, it is possible to further suppress an amount of the organic component flowing in the downstream side of the exhaust pipe.

### Fourth Exemplary Embodiment

Fourth to sixth exemplary embodiments to be described below represent an example where the substrate processing apparatus according the present disclosure is applied to a heating processing apparatus.

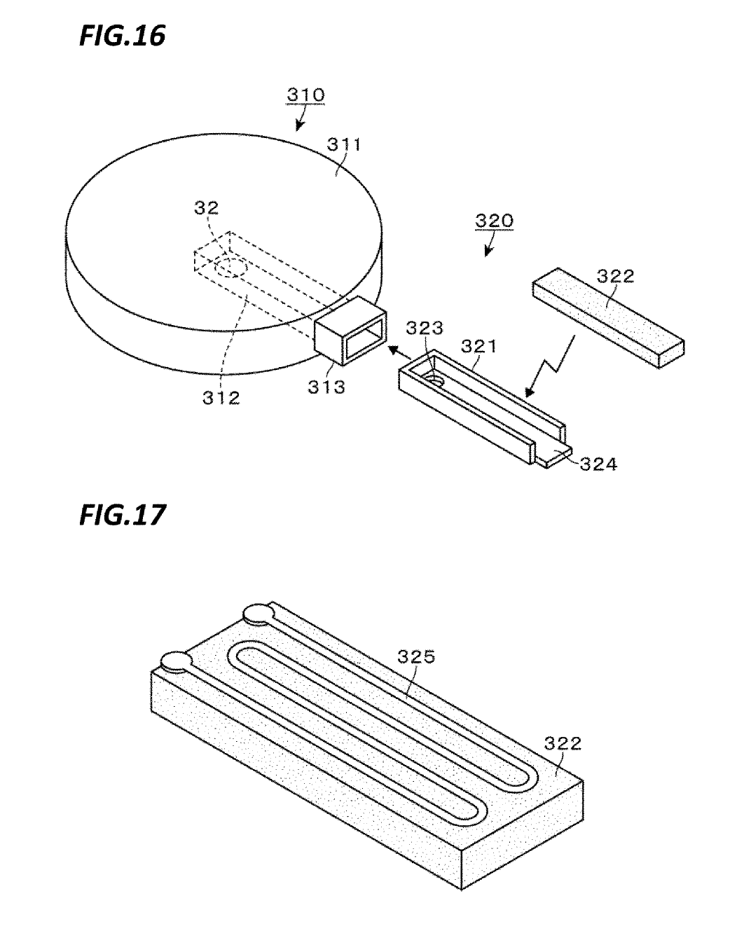

The present disclosure may dispose a porous thermal catalyst (a thermal catalytic material) in the exhaust passage to allow the exhaust flow to pass through the thermal catalyst. A fourth exemplary embodiment of the present disclosure is an exemplary configuration of a heating processing apparatus adopting this technique. The example illustrated in FIGS. 15 and 16 is provided with a structure 310 including a block body 322, which is a molding body obtained by forming a porous thermal catalyst in a block shape, instead of the structural portion including the exhaust passage 300 in the above-described heating processing apparatus illustrated in FIG. 7.

The structure 310 includes a body portion 311 including an exhaust passage 312 of which one end is connected to the exhaust port 32 formed in the cover 22, and a cartridge 320 inserted into the exhaust passage 312 from an exhaust port 313 formed in the other end side of the exhaust passage 312.

The cartridge 320 includes a case body 321 and a block body 322 which is a porous thermal catalyst. The case body 321 is a holder that holds the block body 322, and is formed substantially in a top-opened box shape extending from the upstream side of the exhaust passage 312 toward the downstream side thereof. The case body 321 is formed such that when the cartridge 320 is inserted into the exhaust passage 312, an extremely narrow gap enough not to interfere the attachment/detachment of the cartridge 32 is formed between the wall of the exhaust passage 312 and the cartridge 320. In addition, a hole 323 is formed at the position corresponding to the exhaust port 32 in the bottom surface of one longitudinal end side of the case body 321. The lateral surface of the other longitudinal end side of the case body 320 is opened, and a horizontal projection 324 extends from the bottom surface of the case body 321 to draw the cartridge 320 from the exhaust passage 312.

The block body 322 is configured by attaching a thermal catalytic material to a filter which is a porous catalyst carrier made of, for example, ceramic, and formed in a rectangular column shape that is inserted into the case body 321. As illustrated in FIG. 16, the cartridge 320 which is configured by inserting the block body 322 into the case body 321 is inserted into the exhaust passage 312 from the exhaust port 313. The exhaust port 313 is connected to a duct (not illustrated) connected to a plant power.

In the heating processing apparatus according to this example, the heater 10 provided in, for example, the cover 22 heats the block body 322 within the exhaust passage 312 through the body portion 311 so that the thermal catalyst is activated. In addition, a heater may be provided in the body portion 311 to heat the block body 322. When the atmosphere inside the processing container 2 is exhausted, the exhaust flow passes through the pores of the porous body serving as the block body 322 while flowing in the exhaust passage 312, to be exhausted through the duct.

As described above, the porous block body 322 is disposed to block the exhaust passage 312 and allow the exhaust flow to pass through the pores within the block body 322 so that the area of the thermal catalyst contacted by the sublimate contained in the exhaust flow increases, thereby, improving the decomposition efficiency of the sublimate being exhausted.

In addition, the block body 322 is replaced with a new block body 322 by separating the exhaust port 313 from the duct and drawing the cartridge 320 out from the exhaust passage 312 per processing of a predetermined number of wafers W or predetermined operation time of the heating processing apparatus.

In the heating processing apparatus, during the heating processing, the pores of the block body 322 may be filled with a hardly decomposable substance contained in the exhaust, thereby, reducing the exhaust flow rate. However, according to the heating processing apparatus of the fourth exemplary embodiment, the block body 322 may be quickly drawn out from the exhaust passage 312 to be simply replaced. Hence, the maintenance may be simply conducted so that the time for apparatus operation suspension due to the maintenance (down time) may be reduced.

In addition, the gap of the case body 321 may be filled with, for example, granular ceramic balls each having a surface to which the thermal catalyst is attached, instead of the block body 322. When the substrate provided with the thermal catalyst thereonto is formed in the granular shape, the surface area also increases so that the same effect as described above is obtained.

In addition, in providing the block body 322 within the exhaust passage 312, the block body 322 may be formed such that the density of the ceramic which is the material for the block body 322 increases toward the downstream side (the duct side) of the exhaust passage 312 from the upstream side (the exhaust port 32 side) thereof (the porosity increases toward the upstream side). With this configuration, the pressure loss becomes small when the exhaust passes through the block body 322 so that the exhaust flow smoothly flows in the exhaust passage 312, and a required exhaust flow rate may be easily secured.

In addition, the thermal catalyst heating unit may be embedded in the block body 322. For example, as illustrated in FIG. 17, a heater 325 may be provided to be curved several times inside the block body 322 in the longitudinal direction thereof.

### Fifth Exemplary Embodiment

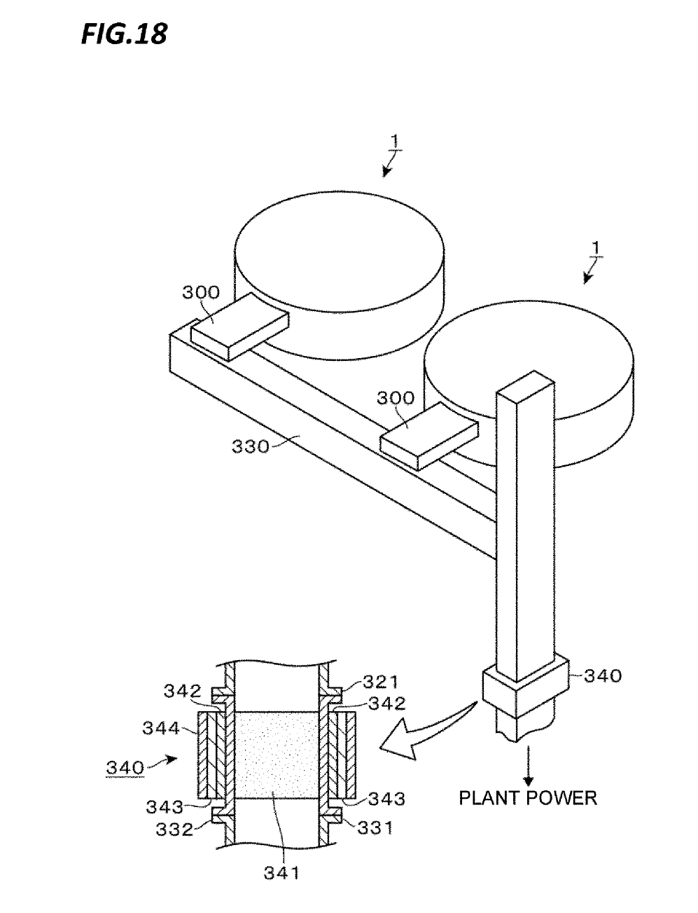

Descriptions will be made on an exemplary embodiment where the present disclosure is applied to a substrate processing apparatus in which separate exhaust passages of a plurality of heating processing apparatuses are connected to an integrated duct as a common exhaust passage, with reference to FIG. 18. In FIG. 18, the reference numeral 300 represents a separate exhaust passage connected to each heating processing apparatus 1, and the reference numeral 330 represents the common integrated duct. The downstream side of the integrated duct 330 is connected to a plant power. In this exemplary embodiment, as illustrated in FIG. 18, a thermal catalyst unit 340 provided with a thermal catalytic material is provided to be freely attachable to/detachable from the integrated duct 330.

For example, as illustrated in the vertical sectional view of FIG. 18, the thermal catalyst unit 340 includes a pipe passage 332 of which a cross-sectional shape corresponds to the cross-sectional shape of the integrated duct 330, and is connected to the integrated duct 330 to be freely attachable to/detachable from the integrated duct 330 through flanges 331 formed at the opposite ends of the pipe passage 332 and flanges of the integrated duct 330 side. A block body 341 as a porous thermal catalyst is fixed within the pipe passage 332. A heater 342 configured to heat the block body 341 is provided over the entire circumference of the outer surface of the pipe passage 332. The circumference of the heater 342 is covered with a heat insulating material 343, and the outer surface of the heat insulating material 343 is covered with a cover 344. In addition, instead of the heat insulating material 343 provided between the cover 344 and the heater 342, cooling water may be allowed to flow therebetween or heat insulation air may be supplied therebetween. In this example, the thermal catalyst is provided in the separate exhaust passage 300 of each heating processing apparatus 1 as described in the second or fourth exemplary embodiment, and furthermore, the thermal catalyst is additionally provided in the integrated duct 330 so that it may be avoided that the sublimate which could not have been removed in the separate exhaust passage 300 is attached and deposited in the downstream side.

In the fifth exemplary embodiment, when the thermal catalyst is not provided in the separate exhaust passage 300 and is provided in the inner surface of the processing container 2, or when the thermal catalyst is provided in neither the separate exhaust passage 300 nor the inner surface of the processing container 2, the thermal catalyst may be provided only in the integrated duct 330. In addition, the heating processing apparatus according to the third exemplary embodiment may additionally adopt the configuration in which the thermal catalyst unit 340 is provided in the integrated duct 330.

### Sixth Exemplary Embodiment

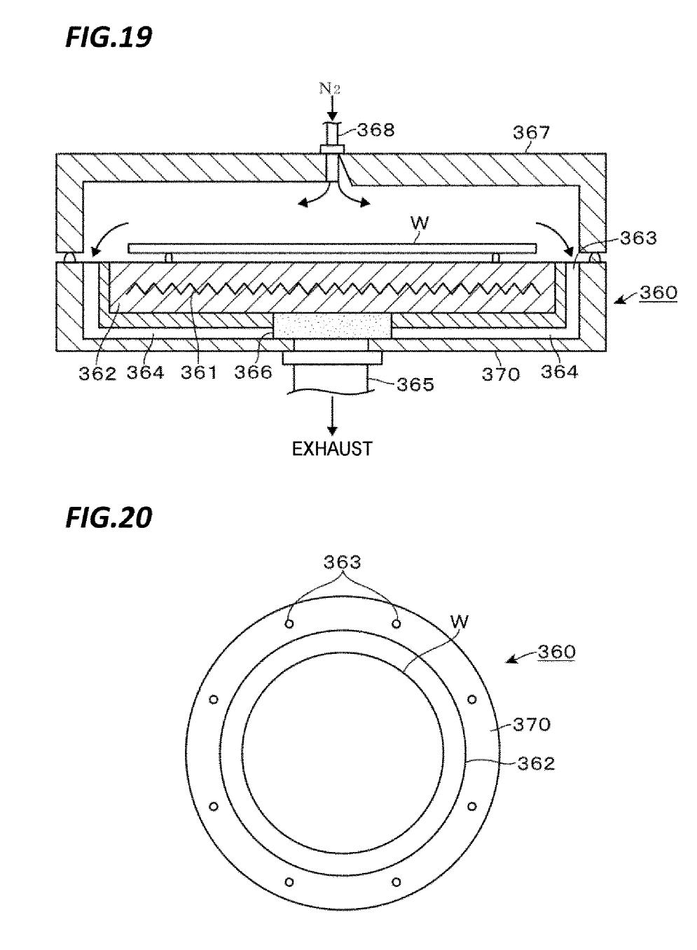

FIGS. 19 and 20 illustrate a heating processing apparatus according to a sixth exemplary embodiment of the present disclosure. In this heating processing apparatus, a placing table 360 that places a wafer W thereon is configured by a heat plate 362 in which a heater 361 as the heating unit is embedded, and a base body 370 into which the heat plate 362 is fitted. A plurality of exhaust ports 363 are opened circumferentially and entirely at the surface of the base body 370 which is the peripheral edge of the placing table 360. Within the base body 370, an exhaust passage 364 having an end opened at each of the exhaust ports 363 extends downwardly and is curved toward the center portion of the placing table 360.

Meanwhile, an exhaust pipe 365 is connected to the center portion of the bottom surface of the placing table 360, and for example, a cylindrical block body 366 is provided therein such that the opening of the exhaust pipe 365 is closed by the bottom surface of the block body 366, and the downstream side of the exhaust passage 364 is blocked by the circumferential surface of the block body 366. That is, the space between the exhaust pipe 365 and the exhaust passage 364 is blocked by the block body 366, and the top surface of the block body 366 is in contact with the bottom surface of the heat plate 362. The block body 366 is formed by attaching, for example, a thermal catalyst to a porous ceramic filter, like the block body 322 used in the fourth exemplary embodiment.

In addition, the exhaust passage 364 may be configured by exhaust passages corresponding to the exhaust ports 363, respectively, and extending vertically, and a common exhaust chamber at which lower ends of the exhaust passages are opened. And, the block body 366 may be provided inside the exhaust chamber.

In addition, a cover 367 is provided above the placing table 360, and a purge gas supply path 368 is connected to the center portion of the ceiling of the cover 367 to supply a purge gas such as, for example, nitrogen gas (N₂ gas). Accordingly, in this exemplary embodiment, the heater 361 serves also as the thermal catalyst heating unit.

With the configuration described above, the wafer W may be heated by the heat plate 362 of the placing table 360, and the block body 366 as the thermal catalyst provided in the exhaust passage 364 may be heated and activated. In addition, when the atmosphere above the wafer W is exhausted from the exhaust ports 363, the exhaust passes through the heated block body 366 to be exhausted so that a sublimate contained in the exhaust may be decomposed.

In addition, as the placing table of the heating processing apparatus described in each of the first to fifth exemplary embodiments, the placing table 360 illustrated in FIGS. 19 and 20 may be applied.

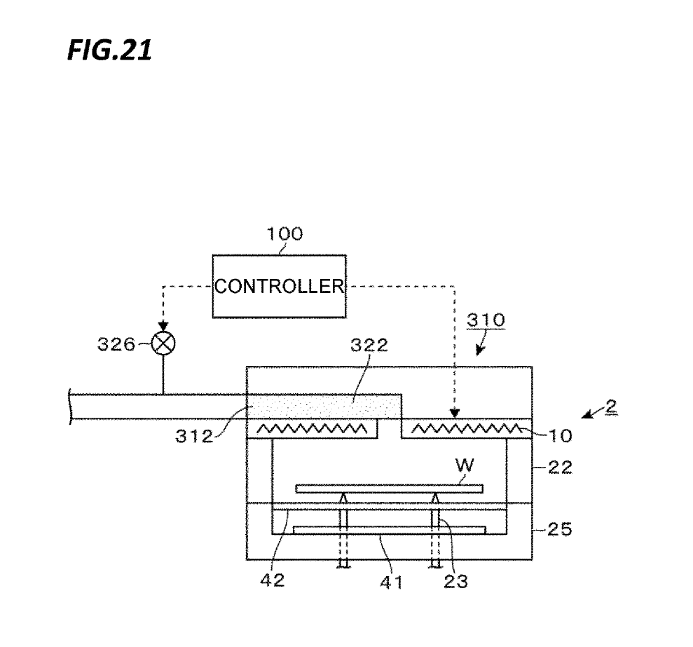

In addition, for example, in the exhaust passage, the exhaust pressure of the downstream side of the section provided with the thermal catalyst may be measured, and when the exhaust pressure exceeds a threshold value, the temperature of the thermal catalyst may be caused to increase. For example, as illustrated in FIG. 21, in the heating processing apparatus described in the fourth exemplary embodiment, an exhaust pressure measuring unit 326 is provided in the downstream side of the section of the exhaust passage 312 where the block body 322 is provided, to measure the exhaust pressure therein. An upper threshold value for the exhaust pressure is stored in advance in the controller 100, and the value measured by the exhaust pressure measuring unit 326 and the upper threshold value for the exhaust pressure are compared with each other. When the exhaust pressure exceeds the upper threshold value, the temperature of the heater 10 as the thermal catalyst heating unit is increased to, for example, 500° C.

For example, in the heating processing apparatus, when the exhaust of the atmosphere is continued after the processing of the wafer W, an undecomposed sublimate may be attached to the block body 322 or the exhaust passage 312, thereby, increasing the pressure loss. As a result, the exhaust flow rate may decrease. Accordingly, by increasing the temperature of the heater 10 when the exhaust pressure increases, the activation of the thermal catalyst increases. Thus, a substance caught in the block body 322 or a substance attached to the exhaust passage 312 may be decomposed, and the pressure loss may be decreased so that the maintenance frequency may be reduced.

In addition, the exhaust pressure measuring unit 326 may be provided at the upstream side of the section provided with the thermal catalyst (the processing container 2 side). Alternatively, the exhaust flow rate may be measured, and when the exhaust flow rate is less than a lower limit value, the temperature of the thermal catalyst heating unit may be increased.

In addition, for example, the heating temperature of the thermal catalyst heating unit may be increased for a predetermined time per processing of a predetermined number of wafers W or elapse of a predetermined operation time of the apparatus. With the configuration described above, a hardly decomposable substance which is attached to the molding body may be periodically removed so that the maintenance frequency may be reduced.

[Verification Test]

As a reference example, a sample was obtained by attaching a polymer (FRP) to a surface of a substrate coated with Cr₂O₃. As a comparative example, a sample was obtained by attaching no polymer to a surface of a substrate coated with Cr₂O₃. When the samples of the reference example and the comparative example were gradually heated from 0° C. to 600° C., a mass change and a heat flow were measured. For the measurement of the heat flow, a differential scanning calorimeter was used.

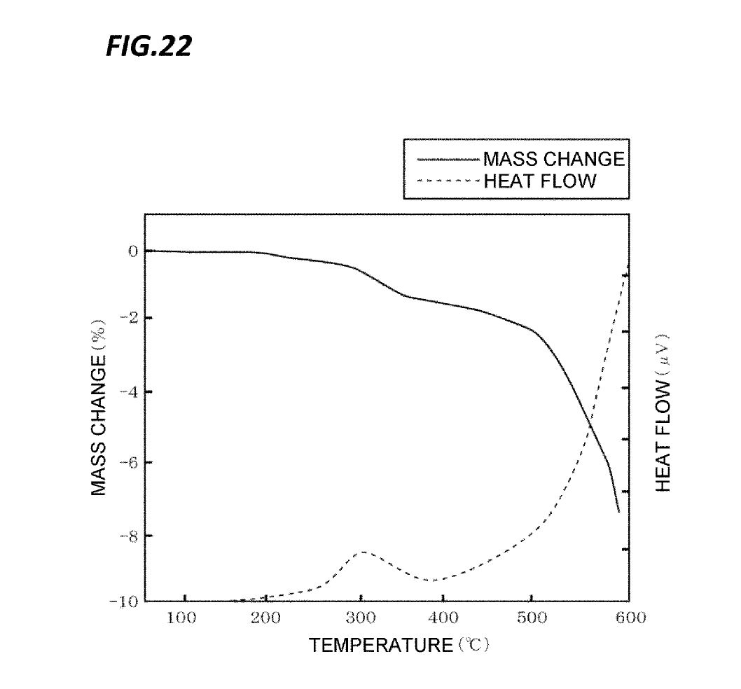

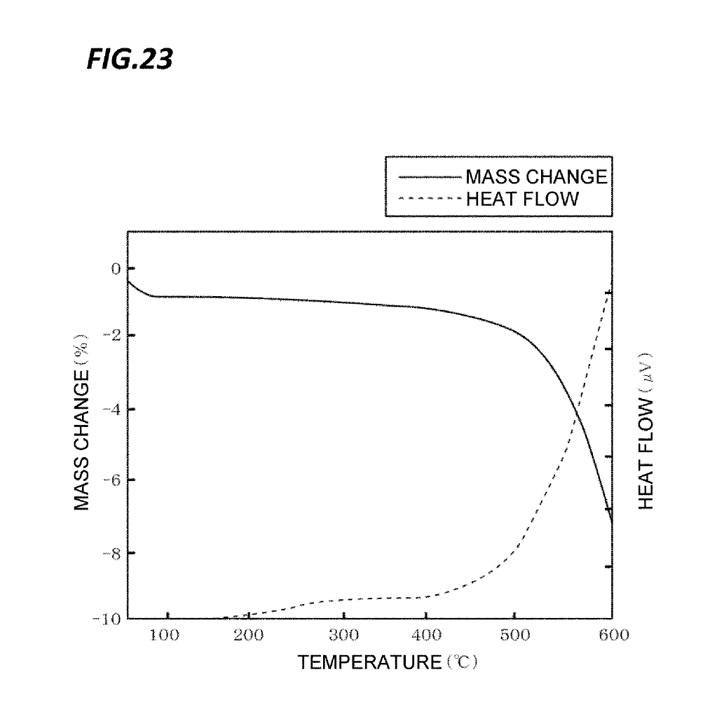

FIGS. 22 and 23 are characteristics diagrams illustrating a mass change rate (mass %) and a heat flow value (μV) in each of the samples of the reference example and the comparative example depending on a temperature. According to the results, in the reference example, the heat flow increases, and the mass decreases, around the temperature of 300° C. to 350° C. It is believed that Cr₂O₃ acts as a thermal catalyst so that the polymer is decomposed. Thus, it may be understood that when Cr₂O₃ is used as a thermal catalyst, the attached polymer may be decomposed by heating the thermal catalyst to about 300° C.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus, comprising:
a processing container provided therein with a placing unit configured to place a processing target substrate thereon;
an exhaust passage configured to exhaust the atmosphere inside the processing container;
a thermal catalytic material formed in at least one of the inner surface of the processing container and the exhaust passage to be heated and therefore thermally activated to decompose a product generated from the processing target substrate by a processing of the processing target substrate; and
a thermal catalyst heating unit configured to heat the thermal catalytic material.

2. The substrate processing apparatus of claim 1, further comprising:
a substrate heating unit configured to heat the processing target substrate placed on the placing unit.

3. The substrate processing apparatus of claim 2, wherein the product generated from the processing target substrate is a sublimate.

4. The substrate processing apparatus of claim 1, wherein the exhaust passage includes a pressure loss section where a pressure loss is larger than that in a downstream side thereof, and
the thermal catalytic material is provided in the pressure loss section.

5. The substrate processing apparatus of claim 1, further comprising:
a light source unit configured to irradiate light to the processing target substrate placed on the placing unit;
a light transmission window configured to partition the light source unit and the atmosphere inside the processing container;
a selection unit configured to select a maintenance mode; and
a controller configured to output a control signal to implement a step of carrying a maintenance substrate provided with the thermal catalytic material into the processing container when the maintenance mode is selected, a step of subsequently heating the maintenance substrate by the substrate heating unit in order to thermally activate the thermal catalytic material, and a step of causing the heated maintenance substrate to approach the light transmission window in order to remove the product attached to the light transmission window.

6. A substrate processing apparatus, comprising:
a processing container provided therein with a placing unit configured to place a processing target substrate thereon;
a substrate heating unit configured to heat the processing target substrate placed on the placing unit;
an exhaust passage configured to exhaust the atmosphere inside the processing container;
a light source unit configured to irradiate light to the substrate placed on the placing unit;
a light transmission window configured to partition the light source unit and the atmosphere inside the processing container;
a selection unit configured to select a maintenance mode; and
a controller configured to output a control signal to implement a step of carrying, into the processing container when the maintenance mode is selected, a maintenance substrate provided with a thermal catalytic material to be heated and therefore thermally activated to decompose a sublimate as a product generated from the processing target substrate by a processing of the processing target substrate, a step of subsequently heating the maintenance substrate by the substrate heating unit in order to activate the thermal catalytic material, and a step of causing the heated maintenance substrate to approach the light transmission window in order to remove the sublimate attached to the light transmission window.

7. The substrate processing apparatus of claim 5, wherein the light source unit serves also as the substrate heating unit.

8. The substrate processing apparatus of claim 5, wherein the light source unit is an ultraviolet ray irradiating lamp.

9. The substrate processing apparatus of claim 5, wherein the step of causing the heated maintenance substrate to approach the light transmission window is performed by a lift pin configured to hold the substrate from the rear surface thereof and move the substrate up and down.

10. The substrate processing apparatus of claim 1, wherein the thermal catalytic material is formed in a layer shape.

11. The substrate processing apparatus of claim 1, wherein the thermal catalytic material is formed into a block body or a particle body obtained by carrying a thermal catalyst in a porous carrier, and provided to block the exhaust passage.

12. The substrate processing apparatus of claim 11, wherein the thermal catalytic material is configured in the manner that a cartridge accommodated in a case body is mounted to be freely attachable to/detachable from the exhaust passage.

13. The substrate processing apparatus of claim 11, further comprising:
a measuring unit configured to measure an exhaust pressure or an exhaust flow rate in the exhaust passage; and
a controller configured to control the heating temperature of the thermal catalyst heating unit to increase when the exhaust pressure measured in the measuring unit exceeds a set value or the measured exhaust flow rate is less than a set value.

14. The substrate processing apparatus of claim 1, further comprising:
a controller configured to control the heating temperature of the thermal catalyst heating unit to temporarily increase per cumulative time of a substrate processing or per number of substrates processed.

15. The substrate processing apparatus of claim 1, wherein a plurality of processing containers are provided to have a common exhaust passage provided such that separate exhaust passages provided in the processing containers, respectively, join with each other in the common exhaust passage, and
the thermal catalytic material is provided in each of the separate exhaust passages, and a thermal catalytic material formed into a block body or a particle body obtained by carrying a thermal catalyst in a porous carrier is provided to block the common exhaust passage.

16. A substrate processing method, comprising:
placing a processing target substrate on a placing unit inside a processing container and processing the processing target substrate;
exhausting the atmosphere inside the processing container through an exhaust passage; and
heating and thermally activating a thermal catalytic material provided in at least one of the inner surface of the processing container and the exhaust passage to decompose a product generated from the processing target substrate by the processing of the processing target substrate.

17. The substrate processing method of claim 16, wherein the processing of the processing target substrate placed on the placing unit is performed in the manner that the substrate is heated by the substrate heating unit.

18. The substrate processing method of claim 16, wherein the thermal catalytic material is formed into a block body or a particle body obtained by carrying a thermal catalyst in a porous carrier and provided to block the exhaust passage, and
the method further comprises increasing the heating temperature of the thermal catalytic material when an exhaust pressure measured by a measuring unit configured to measure an exhaust pressure or an exhaust flow rate in the exhaust passage exceeds a set value or a measured exhaust flow rate is less than a set value.

19. The substrate processing method of claim 16, further comprising temporarily increasing the heating temperature of the thermal catalyst heating unit per cumulative time of the substrate processing or per number of substrates processed.

20. A non-transitory computer-readable storage medium which stores a computer program used for a substrate processing apparatus including a processing container provided therein with a placing unit configured to place a processing target substrate thereon, wherein the computer program includes a step group organized to, when executed, cause a computer to execute the substrate processing method of claim 16.

21. A maintenance method of a substrate processing apparatus including:
a processing container provided therein with a placing unit configured to place a processing target substrate thereon;
a substrate heating unit configured to heat the processing target substrate placed on the placing unit;
an exhaust passage configured to exhaust the atmosphere inside the processing container;
a light source unit configured to irradiate light to the substrate placed on the placing unit; and
a light transmission window configured to partition the light source unit and the atmosphere inside the processing container,
the maintenance method comprising:
carrying, into the processing container, a maintenance substrate provided with a thermal catalytic material to be heated and therefore thermally activated to decompose a sublimate as a product generated from the processing target substrate by the processing of the processing target substrate;
heating the maintenance substrate by the substrate heating unit in order to thermally activate the thermal catalytic material; and
causing the heated maintenance substrate to approach the light transmission window in order to remove the sublimate attached to the light transmission window.

22. A non-transitory computer-readable storage medium which stores a computer program used for a substrate processing apparatus including a processing container provided therein with a placing unit configured to place a processing target substrate thereon, wherein the computer program includes a step group organized to, when executed, cause a computer to execute the maintenance method of claim 21.
